(19) United States
(12) Patent Application Publication
(10) Pub. No.: US 2008/0225503 A1
(43) Pub. Date: Sep. 18, 2008

(54) ELECTRONIC SYSTEM WITH INTEGRATED CIRCUIT DEVICE AND PASSIVE COMPONENT

(75) Inventors: Markus Wollmann, Muenchen (DE); Abdallah Bacha, Muenchen (DE); Andrea Becker, Radeberg (DE); Mathias Boettcher, Dresden (DE); Simon Muff, Mering (DE); Steffen Seifert, Dresden (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/686,827

(22) Filed: Mar. 15, 2007

(51) Int. Cl. H05K 7/00; H01S 4/00

(52) U.S. Cl. 361/782; 29/592.1

(57) ABSTRACT

An electronic system with integrated circuit device and passive component is disclosed. One embodiment provides a printed circuit board, a method for fabricating an electronic system, and an electronic system, including at least one integrated circuit device and at least one passive component, wherein the passive component is arranged at least partially underneath the integrated circuit device.

### BACKGROUND

The invention relates to an electronic system with at least one integrated circuit device and at least one passive component, a printed circuit board, and a method for fabricating an electronic system.

In the case of conventional memory devices, in particular conventional integrated circuit memory devices, one differentiates between functional memory devices (e.g., PLAs, PALs, etc.), and table memory devices, e.g., ROM devices (ROM=Read Only Memory—in particular PROMs, EPROMs, EEPROMs, flash memories, etc.), and RAM devices (RAM=Random Access Memory—in particular e.g., DRAMs and SRAMs).

A RAM device is a memory device for storing data under a predetermined address and for reading out the data under this address later. In the case of SRAMs (SRAM=Static Random Access Memory), the individual memory cells consist e.g., of few, for instance 6, transistors, and in the case of DRAMs (DRAM=Dynamic Random Access Memory) in general only of one single, correspondingly controlled capacitive element.

Conventional integrated circuit devices such as the above memory devices, microprocessor devices, microcontroller devices, etc. usually comprise one or more integrated circuit chips which are mounted into a respective chip package.

When mounting one or several integrated circuit chips into a chip package, respective connections—pads—provided at a respective integrated circuit chip are connected via respective bonding wires with respective connections—e.g., respective pins or balls, etc.—provided at a respective chip package.

The chip package—together with the respective integrated circuit chip(s)—may then be plugged into and/or soldered onto a printed circuit board (PCB), e.g., the motherboard of a computer system, a memory module, etc.

Various different kinds of chip packages are known in the art, such as e.g., dual in-line packages (DIPs), pin grid array (PGA) packages, land grid array (LGA) packages, ball grid array (BGA) packages, etc.

In the case of a pin grid array (PGA) package, one face of the package, e.g., the bottom face thereof, is covered, or partially covered with pins in a grid pattern. The pins can be inserted into respective holes of a printed circuit board, and soldered in place. The pins serve to conduct signals from the integrated circuit provided in the PGA package to the printed circuit board, and/or vice versa.

Further, in the case of a ball grid array (BGA) package, instead of pins, respective balls, e.g., respective solder balls are used which are provided in a grid pattern e.g., on the bottom face of the package.

The BGA package may be placed on a printed circuit board having copper pads in a pattern matching the grid pattern of the balls of the BGA package. The printed circuit board with the BGA package may then be heated, e.g., in a reflow oven or by an infrared heater, causing a solderpaste below the (solder) balls of the BGA package to melt. Surface tension may cause the solder to hold the package in alignment with the printed circuit board, at the correct separation distance, while the solder cools and solidifies, providing a mechanical and electrical connection to the printed circuit board. The balls then may be used to conduct signals from the integrated circuit provided in the BGA package to the printed circuit board, and/or vice versa.

In many applications, several integrated circuit devices may be connected to one single printed circuit board.

In addition to the one or several integrated circuit devices, one or several passive components such as resistors, capacitors, etc. may be connected to the respective printed circuit board.

For instance, several DRAMs together with one or several passive components may be arranged on a single, separate memory module, e.g., a separate memory card.

Several of such memory modules—each e.g., including several DRAMs, and several passive components—may be connected to a respective microprocessor or memory controller provided on a respective motherboard. However, the higher the number of memory modules/DRAMs connected to the microprocessor/memory controller, and the higher the data rate, the worse the quality of the signals exchanged between the memory modules/DRAMs, and the microprocessor/memory controller.

For this reason, “buffered” memory modules are used, e.g., registered DIMMs, or FBDIMMs (Fully Buffered DIMMs), etc. Buffered memory modules comprise—in addition to several DRAMs, and several passive components—one or several buffer devices, receiving some or all of the signals from the microprocessor/memory controller, and relaying them to the respective DRAMs (and/or vice versa).

### SUMMARY

An electronic system is provided, including at least one integrated circuit device and at least one passive component, wherein the passive component is arranged at least partially underneath the integrated circuit device.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a front view of an integrated circuit device and passive components according to an embodiment of the present invention, mounted to a printed circuit board.

FIG. 2 illustrates a side view of an integrated circuit device and passive components illustrated in FIG. 1.

FIG. 3 illustrates an integrated circuit device illustrated in FIGS. 1 and 2, viewed from the bottom.

FIG. 4 schematically illustrates a memory system with buffered memory modules.

FIG. 5 schematically illustrates a section of one of the memory modules illustrated in FIG. 4.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

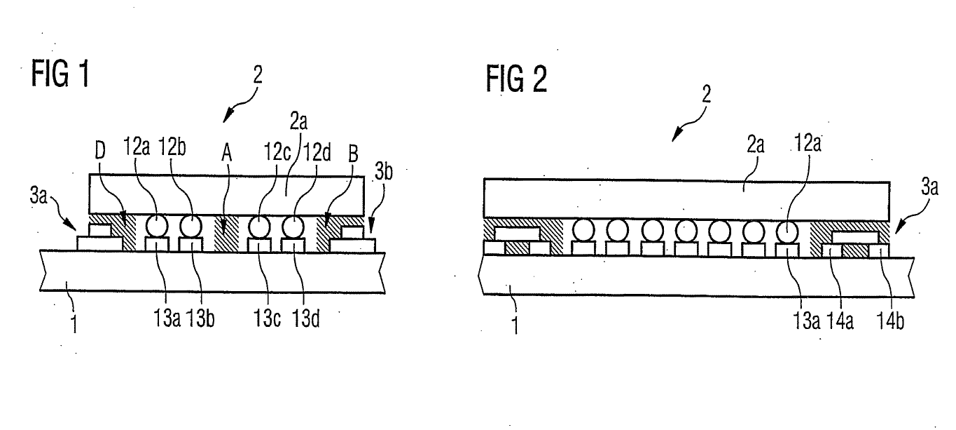

FIG. 1 illustrates a section of a printed circuit board 1 with an integrated circuit device 2 and passive components 3a, 3b.

The integrated circuit device 2, e.g., may be a memory device, a microprocessor device, a microcontroller device, etc., or any other computing and/or data storing semiconductor device, e.g., a PLA, PAL, or ROM device, for instance a PROM, EPROM, EEPROM, or flash memory device, etc., or e.g., a RAM device, for instance an SRAM or DRAM, e.g., a DDR-DRAM or DDR2-DRAM (DDR DRAM=Double Data Rate DRAM), or an integrated circuit device exchanging signals with one of the above memory devices, e.g., a register, a buffer, a PLL, etc.

The integrated circuit device 2, e.g., may include one single integrated circuit chip, e.g., one single memory, microprocessor, or microcontroller chip, etc. mounted into one single chip package 2a.

Alternatively, several integrated circuit chips may be mounted into one single chip package 2a, e.g., two, three, or four chips, etc.

For instance, the chip package 2a may comprise two or four DRAM chips, with one chip stacked upon the other (“stacked DRAM”).

When mounting the one or several integrated circuit chips into the chip package 2a, respective connections, e.g., pads, in particular: respective die pads—provided at a respective integrated circuit chip are connected via respective bonding wires with respective connections—e.g., respective pins or balls 12a, 12b, 12c, 12d, etc.—provided at the chip package 2a.

As a chip package 2a, e.g., a dual in-line package (DIP), pin grid array (PGA) package, land grid array (LGA) package, or ball grid array (BGA) package may be used, or any other suitable kind of chip package (here e.g.: a BGA package 2a), in particular, a respective SMD (surface-mount device) package.

As is illustrated in FIG. 1, the chip package 2a—together with the respective integrated circuit chip or integrated circuit chips provided therein—may be plugged into and/or soldered onto the printed circuit board 1, e.g., the motherboard of a computer system, a memory module, etc.

In the case of a pin grid array (PGA) package, for example, one face of the package, e.g., the bottom face thereof, is (partially) covered with pins in a grid pattern. The pins can be inserted into respective holes of a printed circuit board, and soldered in place. The pins serve to conduct signals from the integrated circuit or integrated circuits provided in the PGA package to the printed circuit board, and/or vice versa.

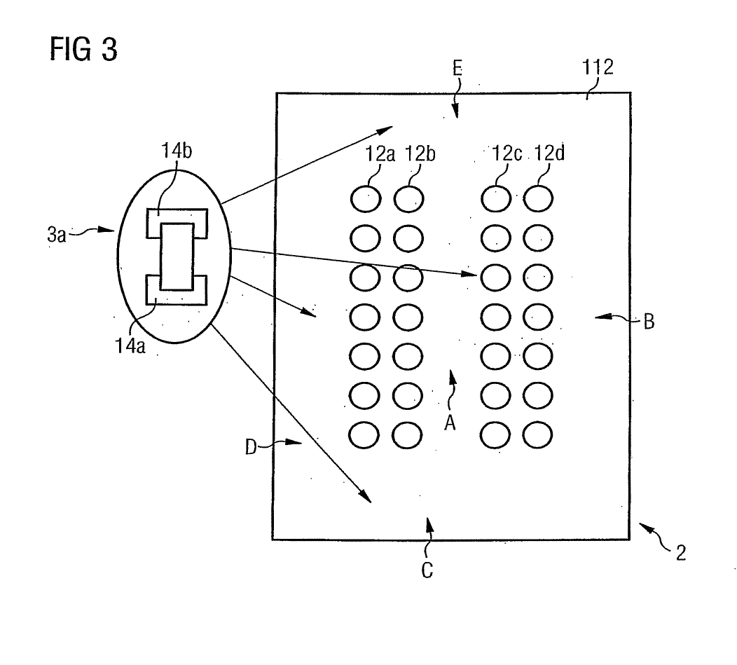

Further, as illustrated in FIGS. 1 and 2, in the case of a ball grid array (BGA) package 2a, instead of pins, respective balls 12a, 12b, 12c, 12d, etc., e.g., respective (solder) balls are used which—as illustrated in FIG. 3—are provided in a grid pattern e.g., on the bottom face 112 of the package 2a.

For instance, as illustrated in FIG. 3, and as will be described in further detail below, some areas of the bottom face of the BGA package 2a are covered with balls 12a, 12b, 12c, 12d, and some other areas of the bottom face are empty, i.e., not covered with balls 12a, 12b, 12c, 12d.

The balls 12a, 12b, 12c, 12d may e.g., be arranged in respective rows and columns.

For instance, in one embodiment, a first area of the bottom face of the BGA package 2a may be covered with (here) two columns and (here) seven rows of balls (the first column of balls of the first area e.g., including the above ball 12a, and the second column of the first area e.g., including the above ball 12b). Further, a second area of the bottom face of the BGA package 2a may also be covered with (here) two columns and (here) seven rows of balls (the first column of balls of the second area e.g., including the above ball 12c, and the second column of the second area e.g., including the above ball 12d).

Any other suitable number of rows and or columns per covered area is also possible (e.g., only one single column of balls per covered area, or e.g., three or four columns, etc.), and a different number of covered and/or non-covered areas, etc. Further, alternatively, one or several additional balls outside the above grid or grids may be provided, e.g., one or several mechanical stabilization balls, etc.

As illustrated in FIG. 3, in one embodiment, e.g., an area between the two covered areas is not covered with balls (here: an area A at the center of the package 2a).

Further, e.g., an area E before, and e.g., an area C behind the row and columns of balls 12a, 12b, 12c, 12d (i.e., an area E before, and an area C behind the above covered areas) are also not covered with balls, as well as e.g., respective areas B, D to the left and to the right of the above covered areas.

As illustrated in FIGS. 1 and 2, the printed circuit board 1 on its top face is provided with copper pads 13a, 13b, 13c, 13d. The copper pads 13a, 13b, 13c, 13d may be arranged in a grid pattern which matches the grid pattern of the balls 12a, 12b, 12c, 12d of the BGA package 2a (such as illustrated in FIG. 3). Instead of copper pads, pads including any suitable other conductive material may be used, e.g., pads made from a respective other metal and/or alloy, etc. Further, the copper pad pattern on the printed circuit board 1 may comprise several additional pads not matching the ball grid pattern of the package 2a, such as to e.g., allow that packages different from the package 2a illustrated in FIG. 1 and 2 (with different ball grid patterns) to be mounted to the printed circuit board instead of the package 2a.

As illustrated in FIGS. 1 and 2, the BGA package 2a may be placed on the printed circuit board 1 such that each ball 12a, 12b, 12c, 12d of the BGA package 2a contacts a respective copper pad 13a, 13b, 13c, 13d of the printed circuit board 1.

The printed circuit board 1 with the BGA package 2a may then be heated, e.g., in a reflow oven or by an infrared heater, etc., e.g., causing a solderpaste below the (solder) balls 12a, 12b, 12c, 12d of the BGA package 2a to melt. Surface tension may cause the solder to hold the BGA package 2a in alignment with the printed circuit board 1, at the correct separation distance, while the solder cools and solidifies, providing a mechanical and electrical connection to the printed circuit board 1. The balls 12a, 12b, 12c, 12d of the BGA package 2a then may be used to conduct signals from the integrated circuit or integrated circuits provided in the BGA package 2a to the printed circuit board 1, and/or vice versa, or for other purposes, e.g., providing power to the integrated circuit(s) in the package 2a, etc.

In one embodiment, as further illustrated in FIG. 1 and 2, one or several separate passive components 3a, 3b (e.g., one, two, four, or more than four or eight passive components, etc.) are provided underneath the bottom face of the BGA package 2a, in particular, one or several passive SMD components.

In particular, the passive component or components 3a, 3b may be arranged underneath one or several of the above areas A, B, C, D, E of the bottom face of the BGA package 2a not covered with balls (see FIG. 3).

For example, one or several passive components may be arranged underneath the above area A of the bottom face of the BGA package 2a, and/or one or several passive components may be arranged underneath the above area B of the bottom face of the BGA package 2a, and/or one or several passive components may be arranged underneath the above area C of the bottom face of the BGA package 2a, and/or one or several passive components may be arranged underneath the above area D of the bottom face of the BGA package 2a, and/or one or several passive components may be arranged underneath the above area E of the bottom face of the BGA package 2a, etc.

The passive components 3a, 3b e.g., may be resistors, or capacitors, or inductive elements, or any other kind of passive components.

Each passive component, e.g., each resistor, capacitor, or inductive element may be provided in a separate (passive component) package or housing (i.e., in a housing separate from the above integrated circuit package 2a). Alternatively,—e.g., in the case of resistor packs—one single separate (passive component) package or housing may also comprise several passive components, e.g., resistors.

As illustrated in FIGS. 1 and 2, and as was explained above, the printed circuit board 1 on its top face, and underneath the bottom face of the BGA package 2a is provided with the above copper pads 13a, 13b, 13c, 13d arranged in a grid pattern which matches the grid pattern of the balls 12a, 12b, 12c, 12d of the BGA package 2a. In addition, and as is also illustrated in FIGS. 1 and 2, the printed circuit board 1 on its top face, and underneath the bottom face of the BGA package 2a is provided with several additional copper pads 14a, 14b, for example, with two or more additional copper pads 14a, 14b for each passive component 3a, 3b to be arranged underneath the bottom face of the BGA package 2a.

The BGA package 2a, and the one or several passive components 3a, 3b may be mounted to the printed circuit board by use of a respective SMT (surface-mount technology) process.

For instance, when fabricating the respective electronic system, in a first process, the above passive component or components 3a, 3b may be placed on the printed circuit board 1 such that e.g., a first connection of a respective passive component 3a, 3b (e.g., provided at a first end section of the passive component, e.g., at the bottom face of the component) contacts a respective first associated copper pad 14a of the printed circuit board 1, and e.g., a second connection of the respective passive component 3a, 3b (e.g., provided at a second end section of the passive component opposing the above first end section, e.g., at the bottom face of the component) contacts a respective second, different associated copper pad 14b of the printed circuit board 1 (see also FIG. 2).

Thereafter, in a second process, the BGA package 2a may be placed on the printed circuit board 1, and above the passive component or components 3a, 3b provided thereon, such that each ball 12a, 12b, 12c, 12d of the BGA package 2a contacts a respective copper pad 13a, 13b, 13c, 13d of the printed circuit board 1.

As illustrated in FIGS. 1 and 2, the size of the balls 12a, 12b, 12c, 12d of the BGA package 2a may be chosen such that the balls 12a, 12b, 12c, 12d prevent that the bottom face of the BGA package 2a contacts the top face of any of the passive components 3a, 3b.

The printed circuit board 1 with the BGA package 2a, and the one or several passive components 3a, 3b may then be heated, e.g., in a reflow oven or by an infrared heater, etc., causing a solderpaste below the (solder) balls 12a, 12b, 12c, 12d of the BGA package 2a, and e.g., respective solder provided on the above additional copper pads 14a, 14b (between the pads 14a, 14b and the respective contacts/connections of the respective passive component 3a, 3b) to melt. Surface tension may cause the solder to hold the BGA package 2a, and the passive component or components 3a, 3b in alignment with the printed circuit board 1, at the correct separation distance between the BGA package 2a and the printed circuit board, and the correct separation distance between the BGA package 2a and the passive component(s) 3a, 3b while the solder cools and solidifies, providing a mechanical and electrical connection to the printed circuit board 1. The balls 12a, 12b, 12c, 12d of the BGA package 2a then may be used to conduct signals from the integrated circuit or integrated circuits provided in the BGA package 2a to the printed circuit board 1, and/or vice versa, or for other purposes, e.g., providing power to the integrated circuit(s) in the package 2a, etc. Further, correspondingly, the above contacts/connections of the passive component(s) 3a, 3b may be used to conduct signals from the passive component(s) 3a, 3b to the printed circuit board 1, and vice versa, or for other purposes, e.g., for decoupling and/or AC shortening, etc.

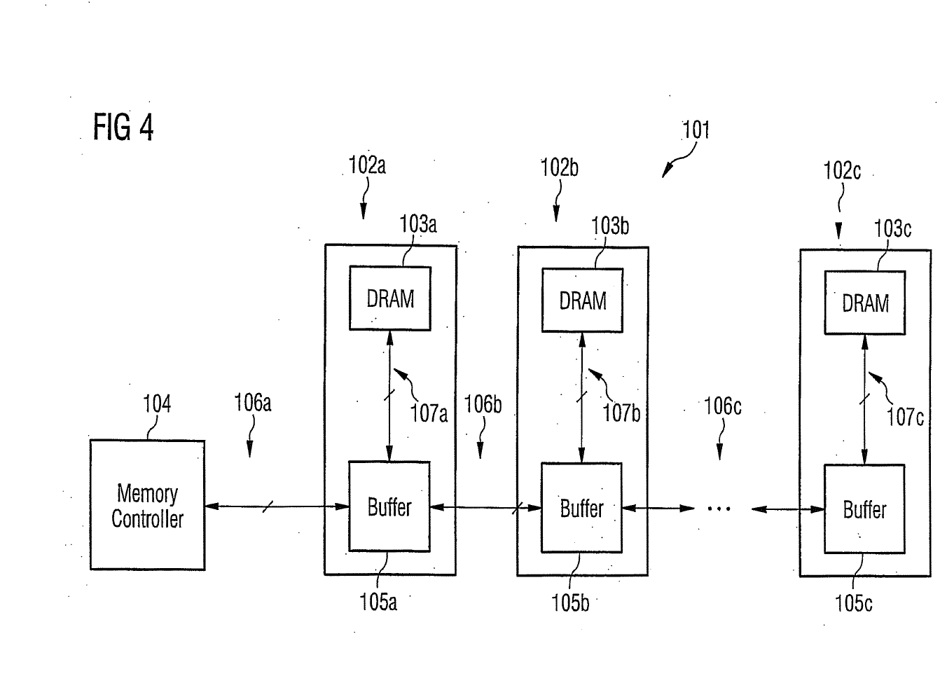

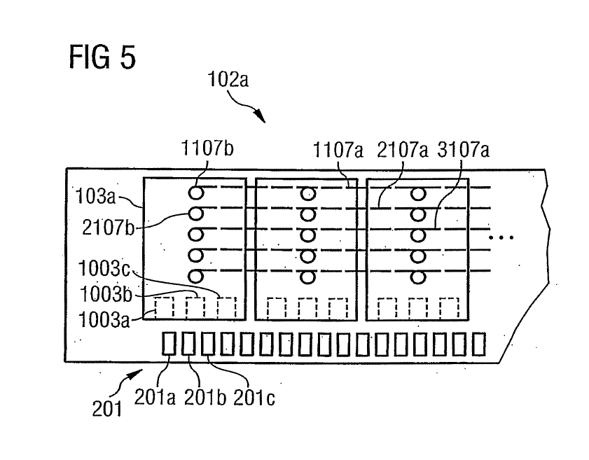

FIG. 4 illustrates an example of a memory system 1 with “buffered” memory modules 102a, 102b, 102c, e.g., FBDIMMs (Fully Buffered DIMMs), or registered DIMMs (in the present case, e.g., respective Very Low Profile DIMMs (VLP DIMMs)). In the memory system 101 illustrated in FIG. 4, e.g., up to eight memory cards/DIMMs 102a, 102b, 102c per channel may be connected to a microprocessor/memory controller 104. Each DIMM 102a, 102b, 102c includes one or several buffer component(s) 105a, 105b, 105c, and several DRAMs 103a, 103b, 103c, e.g., respective DDR2-DRAMs (for sake of simplicity, in FIG. 4 only one DRAM per memory card/DIMM 102a, 102b, 102c is illustrated). A buffer component 105a, 105b, 105c e.g., may comprise a respective buffer, and/or register, etc.

The DIMMs 102a, 102b, 102c may e.g., be plugged into corresponding sockets of a motherboard, which e.g., also includes the above microprocessor/memory controller 104.

As illustrated in FIG. 4, the microprocessor/memory controller 104 may be connected to a first DIMM 102a of the DIMMs 102a, 102b, 102c via a first bus/bus segment 106a. This bus 106a e.g., is used to send respective signals (e.g., address and/or command signals (and alternatively—e.g., in the case of FBDIMMs—additionally respective data signals)) from the microprocessor/memory controller 104 to the buffer component 105a of the first DIMM 102a. Alternatively—e.g., also in the case of FBDIMMs—, the bus 106a may additionally be used to send respective signals from the buffer component 105a of the first DIMM 102a to the microprocessor/memory controller 104.

As further illustrated in FIG. 4, the first DIMM 102a of the DIMMs 102a, 102b, 102c is connected to a second DIMM 102b of the DIMMs 102a, 102b, 102c via a second bus/bus segment 106b, and the second DIMM 102b of the DIMMs 102a, 102b, 102c is connected to a third DIMM via a third bus/bus segment 106c, etc.

The DIMMs 102a, 102b, 102c may work according to the “daisy chain” principle. The buffer component 105a of the first DIMM 102a of the DIMMs 102a, 102b, 102c relays the respective signals (e.g., respective address and/or command signals (and alternatively—e.g., in the case of FBDIMMs—additionally respective data signals)) received via the first bus 106a from the microprocessor/memory controller 104—where required after a respective re-generation—via the second bus 106b to the buffer component 105b of the second DIMM 102b. Correspondingly similar, the buffer component 105b of the second DIMM 102b of the DIMMs 102a, 102b, 102c relays the respective signals (e.g., respective address and/or command signals (and alternatively additionally respective data signals)) received via the second bus 106b from the first DIMM 102a—where required after a respective re-generation—via the third bus 106c to the buffer component 105c of the third DIMM 102c, etc.

In contrast,—in particular e.g., in the case of registered DIMMs—respective data signals (in particular, DQ-signals) e.g., may be exchanged between the above microprocessor/memory controller 104 and the above DRAMs 103a, 103b, 103c directly, i.e., without interference of the above buffer components 105a, 105b, 105c.

As further illustrated in FIG. 4, each DRAM 103a, 103b, 103c is connected to the corresponding buffer component 105a, 105b, 105c via a (uni- or bidirectional) bus 107a, 107b, 107c (in particular, in the case of registered DIMMs, a uni-directional bus, and in the case of FBDIMMs, a respective bidirectional bus).

Further, each buffer component 105a, 105b, 105c is connected to an edge connector of the respective DIMM 102a, 102b, 102c via a respective bus, e.g., a respective x-net bus (such as to exchange the above signals (e.g., respective address and/or command signals (and alternatively additionally respective data signals))—via the edge connector—between the buffer components 105a, 105b, 105c provided on different DIMMs 102a, 102b, 102c, and/or between a respective DIMM 102a, and the microprocessor/memory controller 104, as explained above). The x-net bus may comprise one or several (serial) stub resistors (as explained in further detail below).

Correspondingly similar, e.g., in the case of registered DIMMs (but e.g., not in the case of FBDIMMs), the DRAMs 103a, 103b, 103c may also be connected to the above edge connector of the respective DIMM 102a, 102b, 102c via a respective bus, e.g., a respective x-net bus (such as in the case of registered DIMMs to e.g., exchange—via the edge connector—the above data signals directly between the microprocessor/memory controller 104, and the DRAMs, as explained above). Again, the x-net bus may comprise one or several (serial) stub resistors (as explained in further detail below).

Each buffer component 105a, 105b, 105c knows its position in the above daisy chain. Which of the FBDIMMs 102a, 102b, 102c is being accessed at a certain time by the memory controller 104 may e.g., be determined in the respective buffer component 105a, 105b, 105c by comparing memory module identification data stored there (e.g., an “ID number”) with identification data sent by the memory controller 104 via the above buses 106a, 106b, 106c.

The buffer component 105a, 105b, 105c of an accessed DIMM 102a, 102b, 102c does not only relay the received address and/or command signals (and alternatively additionally respective data signals) via the respective bus 106a, 106b, 106c to the next buffer component in the daisy chain (as explained above), but also relays the signals (where appropriate, in converted form) via the above bus 107a, 107b, 107c to the DRAMs 103a, 103b, 103c provided on the accessed DIMM 102a, 102b, 102c. Further,—in particular in the case of FBDIMMs—signals received by a respective buffer component 105a, 105b, 105c via the above bus 107a, 107b, 107c from an accessed DRAM 103a, 103b, 103c are relayed (where appropriate, in converted form) via a respective one of the buses 106a, 106b, 106c to the previous buffer component in the daisy chain (or—by the buffer component 105a of the first the DIMM 102a—to the memory controller 104). In contrast, as mentioned above, e.g., in the case of registered DIMMs, the data signals from an accessed DRAM 103a, 103b, 103c are sent directly (without interference of a buffer component) to the microprocessor/memory controller 104.

The above DRAMs 103a, 103b, 103c and/or the above buffer components 105a, 105b, 105c may be provided in respective chip packages. Each chip package e.g., may comprise one single integrated circuit chip, or—e.g., in the case of the DRAMs 103a, 103b, 103c—several, e.g., two, three, or four (stacked) chips, etc.

As a chip package for the DRAMs 103a, 103b, 103c and/or buffer components 105a, 105b, 105c, e.g., respective dual in-line packages (DIPs), pin grid array (PGA) packages, land grid array (LGA) packages, or ball grid array (BGA) packages may be used, or any other suitable kind of chip package (here e.g.: respective BGA packages).

In one embodiment, and as illustrated in FIG. 5, and correspondingly similar as explained above with respect to FIG. 1 and 2, one or several separate passive components 1003a, 1003b, 1003c (e.g., one, two, four, or more than four or eight passive components, etc., not included in the BGA packages) may be provided underneath or at least partly underneath the bottom face of the BGA packages of the DRAMs 103a, 103b, 103c. Alternatively or in addition, one or several separate passive components may be provided underneath the bottom face of the BGA packages of the buffer components 105a, 105b, 105c.

In particular, the passive component or components 1003a, 1003b, 1003c may be arranged underneath one or several areas of the bottom face of the respective DRAM or Buffer BGA package not covered with balls (see FIG. 5, and correspondingly similar as explained above with respect to FIGS. 1 and 2).

The passive components 1003a, 1003b, 1003c may be any kind of passive components, e.g., respective SMD passive components, here: respective resistors (in particular, respective stub resistors).

Each passive component 1003a, 1003b, 1003c, e.g., each resistor may be provided in a separate (passive component) package or housing (e.g., in a housing separate from the above DRAM or Buffer package). Alternatively,—e.g., in the case of resistor packs—one single separate (passive component) package or housing may also comprise several passive components, e.g., resistors.

Similar as explained above with respect to FIGS. 1 and 2, the printed circuit boards of the DIMMs 102a, 102b, 102c on their top faces, and underneath the bottom faces of the BGA packages of the DRAMs 103a, 103b, 103c and/or buffer components 105a, 105b, 105c may be provided with respective copper pads arranged in a grid pattern which matches the grid patterns of respective balls of the BGA packages of the DRAMs 103a, 103b, 103c and/or buffer components 105a, 105b, 105c. In addition, and also similar as explained above with respect to FIGS. 1 and 2, the printed circuit boards of the DIMMs 102a, 102b, 102c on their top faces, and underneath the bottom faces of the BGA packages of the DRAMs 103a, 103b, 103c and/or buffer components 105a, 105b, 105c may be provided with several additional copper pads, for example, with two or more additional copper pads for each passive component 1003a, 1003b, 1003c to be arranged underneath the bottom face of a respective BGA package.

The BGA packages of the DRAMs 103a, 103b, 103c and/or buffer components 105a, 105b, 105c, and the one or several passive components 1003a, 1003b, 1003c may be mounted to the printed circuit boards of the DIMMs 102a, 102b, 102c by use of a respective SMT (surface-mount technology) process, e.g., similar as explained above with respect to FIGS. 1 and 2.

For instance, when fabricating a respective DIMM 102a, 102b, 102c, in a first process, the above passive component or components 1003a, 1003b, 1003c may be placed on the respective printed circuit board such that e.g., a first connection of a respective passive component 1003a, 1003b, 1003c contacts a respective first associated copper pad of the printed circuit board, and e.g., a second connection of the respective passive component 1003a, 1003b, 1003c contacts a respective second, different associated copper pad of the printed circuit board.

Thereafter, in a second process, the above DRAM and/or buffer component BGA packages may be placed on the printed circuit board, above the passive component or components 1003a, 1003b, 1003c, such that each ball of a respective BGA package contacts a respective copper pad of the printed circuit board.

The size of the balls of the BGA packages may be chosen such that the balls prevent that the bottom faces of the BGA packages contact the top face of any of the passive components 1003a, 1003b, 1003c.

The printed circuit board with the BGA packages, and the one or several passive components 1003a, 1003b, 1003c may then be heated, e.g., in a reflow oven or by an infrared heater, etc., causing a solderpaste below the (solder) balls of the BGA packages, and e.g., respective solder provided on the above additional copper pads to melt. After the solder cools and solidifies, the balls of the BGA packages may be used to conduct signals from the integrated circuit or integrated circuits provided in the BGA packages to the printed circuit board, and/or vice versa, or for other purposes, e.g., providing power to the integrated circuit(s), etc. Further, correspondingly, the above contacts/connections of the passive component(s) 1003a, 1003b, 1003c may be used to conduct signals from the passive component(s) 1003a, 1003b, 1003c to the printed circuit board, and/or vice versa, or for other purposes, e.g., for decoupling and/or AC shortening, etc.

Each DIMM 102a, 102b, 102c includes one or several edge connectors 201 (see also FIG. 5), for instance, respective gold finger edge connectors. Each edge connector 201 includes several contact surfaces 201a, 201b, 201c or “fingers” used to contact respective associated connections at the motherboard when the DIMM 102a, 102b, 102c is plugged into the corresponding socket of the motherboard.

As illustrated in FIG. 5, at least some or all of the above passive components 1003a, 1003b, 1003c arranged underneath the bottom faces of the DRAM and/or buffer component BGA packages are arranged under areas of the bottom faces of the BGA packages which are close to or in the vicinity of the above edge connector(s) 201 (here: under areas adjacent to that front or side face of the package which is located closest to the above edge connector(s) 201).

Each buffer component 105a, 105b, 105c, and alternatively—in addition to each buffer component 105a, 105b, 105c—also each DRAM 103a, 103b, 103c may be connected to the respective edge connector(s) 201 of the respective DIMM 102a, 102b, 102c via the above (x-net) bus or busses (e.g., with the above stub resistors connected serially within the respective signal lines, see below).

Further, one or several or all of the above passive components 1003a, 1003b, 1003c provided underneath the bottom faces of the above BGA packages may be respective stub resistors, i.e., may be connected to or be part of the above (x-net) bus/(x-net) busses (i.e., a respective address and/or command bus (CA-bus), and/or a respective data bus (DQ-bus), etc.) (see below).

The stub resistors e.g., may be used to ensure a good signal integrity of the above signals exchanged via the edge connector 201 between the buffer components/DRAMs provided on one respective DIMM and one of the further DIMMs, and/or the microprocessor/memory controller 104.

In particular, for example, a respective contact surface 201a of the edge connector 201 may be connected via a respective line provided in or on the printed circuit board with a first connection or contact of a respective passive component 1003a, 1003b, 1003c, e.g., stub resistor, and a second connection or contact of the respective passive component 1003a, 1003b, 1003c, e.g., stub resistor may be connected via a further line provided in or on the printed circuit board with a respective BGA package ball of the respective buffer component 105a, 105b, 105c or DRAM 103a, 103b, 103c, etc.

Due to the above-explained arrangement of the passive component(s) 1003a, 1003b, 1003c, e.g., the above stub resistor(s), the length of the above line between the edge connector 201 and the passive component may be kept relatively short (e.g., shorter than e.g., 1 cm, in particular, shorter than e.g., 0.7 cm, e.g., between 3 and 4 mm). Hence, e.g., a relatively good signal integrity may be achieved. Further, also due to the above-explained arrangement of the passive component(s) 1003a, 1003b, 1003c, the orientation of the DRAMs 103a, 103b, 103c may be kept as illustrated in FIG. 5. Hence, respective lines 1107a, 2107a, 3107a of the above bus 107a (e.g., a corresponding address and/or command bus (CA-bus)) connecting on a respective DIMM 102a the DRAMs 103a with each other, and with the respective buffer/register component 105a (see also FIG. 4) may be arranged essentially parallel, and may be routed relatively straight and short. This may lead e.g., to a relatively low flight time which e.g., might be required for a high speed performance of the memory module. A relatively straight routing of the bus may also reduce the layout space requirements, which may save an additional PCB layer and thus decrease costs. The lines 1107a, 2107a, 3107a of the above bus 107a may e.g., be arranged at an inner layer of the printed circuit board of the respective DIMM 102a, and may be connected to the above BGA balls of the DRAMs 103a/buffer component 105a, and/or with other layers of the printed circuit board by use of respective vias (plated through holes) 1107b, 2107b provided in the printed circuit board.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. An electronic system comprising:
at least one integrated circuit device; and
at least one passive component, wherein the passive component is arranged at least partially underneath the integrated circuit device.

2. The system of claim 1 comprising:
wherein the integrated circuit device comprises a package, and the passive component is arranged underneath a bottom face of the package.

3. The system of claim 1, comprising wherein the passive component comprises a resistor.

4. The system of claim 1, comprising wherein the passive component comprises a capacitor or inductor.

5. The system of claim 2, comprising wherein the passive component is provided underneath an area of the bottom face of the package not covered with balls or pins.

6. The system of claim 5, comprising wherein the package is a dual in-line package (DIP).

7. The system of claim 5, comprising wherein the package is a pin grid array (PGA) package.

8. The system of claim 5, comprising wherein the package is a ball grid array (BGA) package.

9. The system of claim 2, comprising wherein the package is a SMD (surface-mount device) package.

10. The system of claim 1, comprising wherein the integrated circuit device comprises a ROM device.

11. The system of claim 1, comprising wherein the integrated circuit device comprises a RAM device.

12. The system of claim 11, comprising wherein the integrated circuit device comprises a DRAM device.

13. A printed circuit board assembly, comprising:
a printed circuit board;
at least one integrated circuit device; and
at least one passive component, wherein the passive component is arranged at least partially between the integrated circuit device, and the printed circuit board.

14. The printed circuit board of claim 13, comprising wherein the integrated circuit device comprises a package, and the passive component is arranged at least partially between a bottom face of the package, and a top face of the printed circuit board.

15. The printed circuit board of claim 13, comprising several DRAM integrated circuit devices.

16. The printed circuit board of claim 15, wherein the passive component comprises a resistor or capacitor.

17. The printed circuit board of claim 16, comprising an edge connector.

18. The printed circuit board of claim 17, comprising wherein the resistor is connected to the edge connector.

19. An electronic system comprising:
a Fully Buffered DIMM comprising at least one integrated circuit device and at least one passive component, wherein the passive component is arranged at least partially underneath the integrated circuit device.

20. A method for fabricating an electronic system, comprising:
attaching a passive component to a printed circuit board; and
attaching an integrated circuit device to the printed circuit board such that the passive component is arranged at least partially underneath a bottom face of the integrated circuit device.

21. The method of claim 20, comprising:
electrically connecting the passive component and the integrated circuit device to the printed circuit board when attaching the integrated circuit device and the passive component.

22. The method of claim 21, wherein the passive component comprises a resistor or capacitor.

23. The method of claim 21, wherein the integrated circuit device comprises a DRAM device.
